(19) United States
(12) Patent Application Publication
(10) Pub. No.: US 2026/0096376 A1
(43) Pub. Date: Apr. 2, 2026

(54) SUBSTRATE PROCESSING APPARATUS AND SUBSTRATE PROCESSING METHOD

(71) Applicant: Tokyo Electron Limited, Tokyo (JP)

(72) Inventors: Shota UMEZAKI, Koshi City (JP); Takahiro HAYASHIDA, Koshi City (JP); Mikio NAKASHIMA, Koshi City (JP)

(21) Appl. No.: 19/333,444

(22) Filed: Sep. 19, 2025

(30) Foreign Application Priority Data
Sep. 27, 2024 (JP) 2024-169087

(51) Int. Cl. H01L 21/67; H01L 21/02

(52) U.S. Cl. CPC H10P 72/0408; H10P 70/80

(57) ABSTRACT

A substrate processing apparatus includes: a processing container; a holder holding a substrate horizontally; and a fluid supplier supplying a processing fluid from a side of the processing container, wherein, when the substrate is held, a first distance between a first virtual plane, including an upper surface of the substrate, and a ceiling surface of the processing container is different from a second distance between a second virtual plane, including a lower surface of the substrate, and a bottom surface of the processing container, wherein the fluid supplier includes a nozzle changing a flow of the processing fluid and including first and second dischargers discharging first and second discharge amounts of the processing fluid respectively from positions above the first virtual plane and below the second virtual plane, and a magnitude relationship between the first and second discharge amounts corresponds to a magnitude relationship between the first and second distances.

### CROSS-REFERENCE TO RELATED APPLICATION

This application is based upon and claims the benefit of priority from Japanese Patent Application No. 2024-169087, filed on Sep. 27, 2024, the entire contents of which are incorporated herein by reference.

### TECHNICAL FIELD

The present disclosure relates to a substrate processing apparatus and a substrate processing method.

### BACKGROUND

Patent Document 1 discloses changing a flow direction of a processing fluid so that, when the processing fluid is supplied into a processing container, the flow does not reach an outer end of a substrate in a radial direction of the substrate.

### PRIOR ART DOCUMENTS

### Patent Documents

Patent Document 1: Japanese Patent Laid-Open Publication No. 2024-84683

### SUMMARY

According to one embodiment of the present disclosure, a substrate processing apparatus includes: a processing container; a holder configured to hold a substrate in a horizontal orientation at a holding position inside the processing container; and a fluid supplier configured to supply a processing fluid into the processing container from a lateral side of the processing container, wherein, in a state in which the substrate is held by the holder, a first distance between a first virtual plane, including an upper surface of the substrate, and a ceiling surface of the processing container is different from a second distance between a second virtual plane, including a lower surface of the substrate, and a bottom surface of the processing container, wherein the fluid supplier includes a nozzle configured to change a flow of the processing fluid, wherein the nozzle includes: a first discharger configured to discharge a first discharge amount of the processing fluid from a position above the first virtual plane; and a second discharger configured to discharge a second discharge amount of the processing fluid from a position below the second virtual plane, and wherein a magnitude relationship between the first discharge amount and the second discharge amount corresponds to a magnitude relationship between the first distance and the second distance.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram illustrating a substrate processing apparatus according to an embodiment.

FIG. 2 is a horizontal cross-sectional view illustrating an example of a processor.

FIG. 3 is a diagram illustrating a nozzle according to a first example.

FIG. 4 is a diagram illustrating a nozzle according to a second example.

FIG. 5 is a flowchart illustrating a substrate processing method according to an embodiment.

FIG. 6 is a diagram illustrating a pressure variation in each process.

FIG. 7 is a diagram 1 illustrating analysis results of a processing fluid flow.

FIG. 8 is a diagram 2 illustrating analysis results of a processing fluid flow.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, exemplary embodiments of the present disclosure, which are non-limitative, will be described with reference to the accompanying drawings. In all the accompanying drawings, the same or corresponding members or components are denoted by the same or corresponding reference numerals, and repeated descriptions thereof will be omitted.

In the following description, an XYZ Cartesian coordinate system is used for explanatory purposes only and does not limit an orientation of a substrate processing apparatus. A view in an XY plane is referred to as a plane view. In some cases, when viewed from an arbitrary point, a positive side of a Z-axis is referred to as upward, and a negative side of the Z-axis is referred to as downward.

### [Substrate Processing Apparatus]

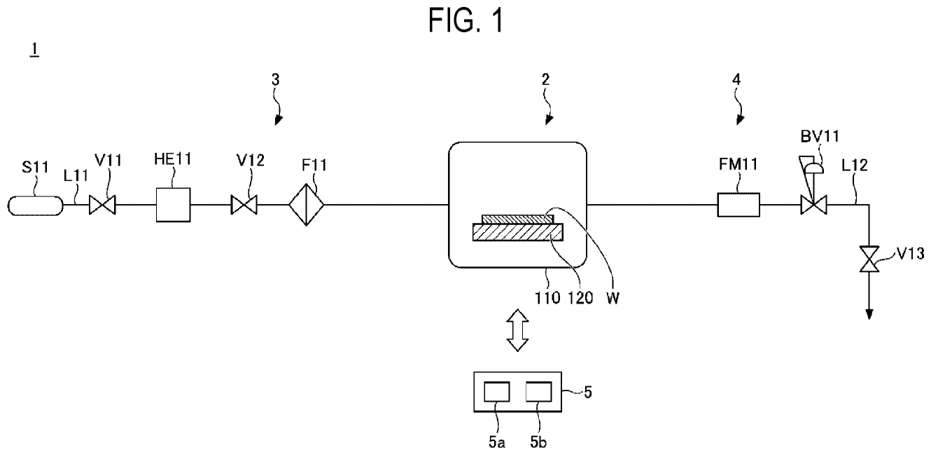

A substrate processing apparatus 1 according to an embodiment is described with reference to FIG. 1. FIG. 1 is a schematic diagram illustrating the substrate processing apparatus 1 according to the embodiment.

The substrate processing apparatus 1 is an apparatus that dries liquid, such as isopropyl alcohol (IPA), adhered to a substrate W using a processing fluid in a supercritical state. The substrate processing apparatus 1 includes a processor 2, a fluid supply system 3, a drain 4, and a control circuit 5.

The processor 2 includes a processing container 110 and a holder 120. The processing container 110 is a container in which a processing space capable of accommodating the substrate W is formed. The substrate W may be, for example, a semiconductor wafer. The holder 120 is provided inside the processing container 110. The holder 120 holds the substrate W in a horizontal orientation at a holding position inside the processing container 110. The processor 2 may include a pressure sensor that detects an internal pressure of the processing container 110 and a temperature sensor that detects an internal temperature of the processing container 110. Details of the processor 2 are described later.

The fluid supply system 3 includes a supply passage L11. The supply passage L11 is connected to the processing container 110. The supply passage L11 supplies a fluid into the processing container 110. A fluid supply source S11, an opening/closing valve V11, a heating mechanism HE11, an opening/closing valve V12, and a filter F11 are sequentially provided at the supply passage L11 from upstream. An orifice, an opening/closing valve, a temperature sensor, a pressure sensor, a line heater, and the like, which are not illustrated, may be further provided at the supply passage L11.

The fluid supply source S11 includes a supply source of a fluid. The fluid includes, for example, a processing fluid. The processing fluid may be, for example, carbon dioxide (CO₂). The fluid may include an inert gas. The inert gas may be, for example, nitrogen (N₂) gas.

The opening/closing valve V11 is a valve that switches a flow of the fluid ON and OFF. The opening/closing valve V11 allows the fluid to flow to the downstream heating mechanism HE11 in an open state and does not allow the fluid to flow to the downstream heating mechanism HE11 in a closed state.

The heating mechanism HE11 heats the fluid to a set temperature and supplies the fluid of the set temperature downstream. The heating mechanism HE11 may include a heater.

The opening/closing valve V12 is a valve that switches a flow of the fluid ON and OFF. The opening/closing valve V12 allows the fluid to flow to the downstream filter F11 in an open state and does not allow the fluid to flow to the downstream filter F11 in a closed state.

The filter F11 filters the fluid flowing through the supply passage L11 and removes foreign substances contained in the fluid. This makes it possible to suppress generation of particles on a surface of the substrate W during substrate processing that uses the fluid.

The drain 4 includes a drain passage L12. The drain passage L12 is connected to the processing container 110. The drain passage L12 drains the fluid from an interior of the processing container 110. A flow meter FM11, a back pressure valve BV11, and an opening/closing valve V13 are sequentially provided at the drain passage L12 from upstream. An opening/closing valve, a temperature sensor, a pressure sensor, a line heater, and the like, which are not illustrated, may be further provided at the drain passage L12.

The flow meter FM11 detects a flow rate of the fluid flowing through the drain passage L12. The flow meter FM11 is, for example, a mass flow meter.

When a primary-side pressure of the drain passage L12 exceeds a set pressure, the back pressure valve BV11 maintains the primary-side pressure at the set pressure by adjusting a valve opening degree and allowing the fluid to flow to a secondary side. For example, the set pressure of the back pressure valve BV11 is adjusted by the control circuit 5 based on an output of the flow meter FM11.

The opening/closing valve V13 is a valve that switches a flow of the fluid ON and OFF. The opening/closing valve V13 allows the fluid to flow to the downstream drain passage L12 in an open state and does not allow the fluid to flow to the downstream drain passage L12 in a closed state.

The control circuit 5 receives measurement signals from various sensors and transmits control signals to various functional elements. The measurement signals include, for example, a detection signal from a temperature sensor, a detection signal from a pressure sensor, and a detection signal from the flow meter FM11. The control signals include, for example, opening/closing signals for the opening/closing valves V11, V12, and V13 and a set pressure signal for the back pressure valve BV11.

The control circuit 5 is, for example, a computer. The control circuit 5 includes a calculator 5a, such as a central processing unit (CPU), and a storage 5b such as a memory and the like. Programs for controlling various processes executed in the substrate processing apparatus 1 are stored in the storage 5b. The control circuit 5 controls operations of the substrate processing apparatus 1 by causing the calculator 5a to execute the programs stored in the storage 5b.

The control circuit 5 includes an electronic circuit such as a CPU, a field programmable gate array (FPGA), or an application specific integrated circuit (ASIC) and performs various control operations described in the present disclosure by executing instruction codes stored in the memory or by being designed as a circuit for a specific purpose.

### [Processor]

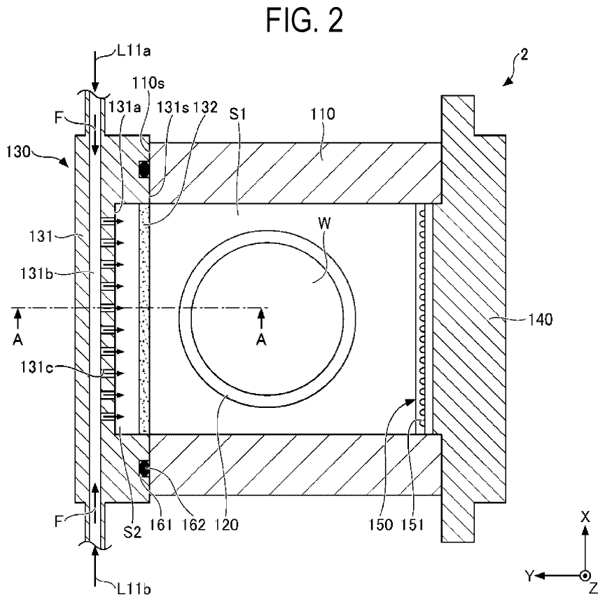

An example of the processor 2 is described with reference to FIG. 2. FIG. 2 is a horizontal cross-sectional view illustrating the example of the processor 2.

The processor 2 includes the processing container 110, the holder 120, a fluid supplier 130, a cover body 140, and a fluid drain 150.

The processing container 110 forms a processing space S1 capable of accommodating the substrate W in an interior of the processing container 110. The processing space S1 is partitioned by being covered from an outside by the processing container 110. Both ends of the processing space S1 (an end on a positive side of the Y-axis and an end on a negative side of the Y-axis) are open without being covered by the processing container 110. Openings at the two ends of the processing space S1 face each other. The openings at the two ends of the processing space S1 are positioned to sandwich the substrate W held at the holding position. The processing container 110 includes a first surface 110s that surrounds the opening of the processing space S1 on the positive side of the Y-axis.

The holder 120 is provided inside the processing container 110. The holder 120 holds the substrate W in a horizontal orientation at the holding position inside the processing container 110.

The fluid supplier 130 includes a supply body 131 and a nozzle 132.

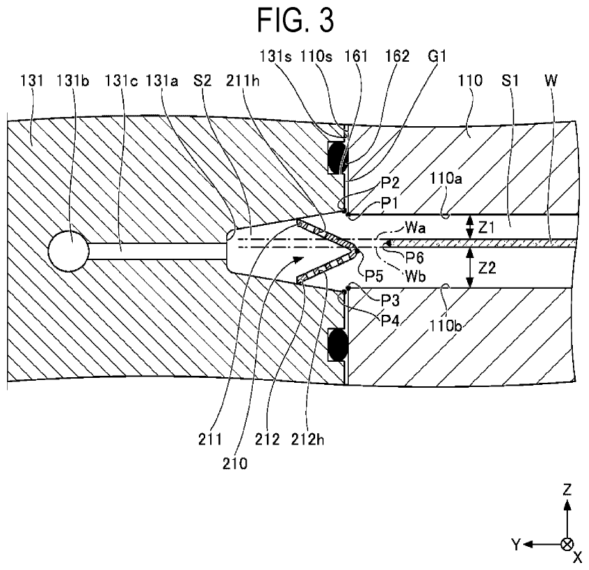

The supply body 131 covers the opening of the processing space S1 on the positive side of the Y-axis. The supply body 131 is formed, for example, by stainless steel. The supply body 131 includes a second surface 131s that faces the first surface 110s of the processing container 110. A seal groove 161 is provided on the second surface 131s of the supply body 131. The seal groove 161 surrounds the opening of the processing space S1 on the positive side of the Y-axis. The seal groove 161 communicates with the processing space S1 through a gap G1 (see FIG. 3) between the first surface 110s and the second surface 131s. The seal groove 161 may be provided between the first surface 110s and the second surface 131s or may be provided on the first surface 110s. A sealing member 162 is provided in the seal groove 161. The sealing member 162 seals the gap G1 between the first surface 110s and the second surface 131s. Thereby, the processing space S1 is hermetically sealed. The sealing member 162 is, for example, an O-ring.

The supply body 131 includes a recess 131a, an inner passage 131b, and discharge ports 131c.

The recess 131a is provided at the supply body 131 on a side toward the processing space S1. The recess 131a forms a supply space S2 communicating with the processing space S1.

The inner passage 131b is provided inside the supply body 131. The inner passage 131b extends along the X-axis. A first branch passage L11a and a second branch passage L11b, which are branched from the supply passage L11, are respectively connected to openings at both ends of the inner passage 131b. A processing fluid F from the first branch passage L11a and the second branch passage L11b is supplied to the inner passage 131b.

The discharge ports 131c are provided along the inner passage 131b. Through each of the discharge ports 131c, the inner passage 131b and the supply space S2 communicate with each other. Each of the discharge ports 131c is provided radially outside the substrate W held at the holding position. Each of the discharge ports 131c discharges the processing fluid F toward the supply space S2. The discharge ports 131c may be distributed and disposed along the X-axis over an entire range of the substrate W held at the holding position. The discharge ports 131c may be provided in multiple stages along the Z-axis.

The nozzle 132 is provided, for example, in the supply space S2. The nozzle 132 may be provided in the processing space S1. The nozzle 132 may be provided across the processing space S1 and the supply space S2. The nozzle 132 is, for example, provided between the discharge ports 131c and the substrate W held at the holding position. The nozzle 132 may be detachably installed on the supply body 131. In this case, it is easy to replace the nozzle 132. Details of the nozzle 132 are described later.

The cover body 140 covers the opening of the processing space S1 on the negative side of the Y-axis. A sealing member, which is not illustrated, is provided between the cover body 140 and the processing container 110. The sealing member seals a gap between the cover body 140 and the processing container 110. Thereby, the processing space S1 is hermetically sealed.

The fluid drain 150 is provided on the negative side of the Y-axis at the processing space S1. The fluid drain 150 includes drain ports 151. The drain ports 151 are open, for example, toward the cover body 140. In this case, the processing fluid flows through to the end of the processing space S1 on the negative side of the Y-axis, making it easy to form a laminar flow near an upper surface of the substrate W. The drain ports 151 may be open toward the nozzle 132. The drain ports 151 may be open toward a positive side of the Z-axis. The drain ports 151 are provided side by side along the X-axis. The drain ports 151 may be distributed and disposed along the X-axis over the entire range of the substrate W held at the holding position. The drain ports 151 may be disposed in multiple stages along the Z-axis. The drain ports 151 are connected to the drain passage L12. The processing fluid F inside the processing space S1 is drawn in through the drain ports 151 and drained.

### [Nozzle]

### First Example

A nozzle 210 according to a first example is described with reference to FIG. 3. The nozzle 210 is applicable as the nozzle 132 described above. FIG. 3 is a diagram illustrating the nozzle 210 according to the first example. FIG. 3 is a cross-sectional view taken along line A-A in FIG. 2. In FIG. 3, illustration of the holder 120 is omitted.

The nozzle 210 is provided in the supply space S2. The nozzle 210 extends along the X-axis. The nozzle 210 has a V shape with an apex on a side toward the negative side of the Y-axis in a vertical cross-section perpendicular to the X-axis. The nozzle 210 includes a first discharger 211 and a second discharger 212. The first discharger 211 and the second discharger 212 are formed, for example, by a single seamless member. The first discharger 211 and the second discharger 212 are formed by, for example, processing a plate-shaped member. The first discharger 211 and the second discharger 212 may be formed by bonding separate individual members to each other.

The first discharger 211 is inclined upward from the negative side of the Y-axis toward the positive side of the Y-axis. The first discharger 211 is provided with first holes 211h through which the processing fluid is able to flow. The first holes 211h are provided side by side along the X-axis. Each first hole 211h may be arranged so as to be misaligned with each discharge port 131c in the X-axis direction. In this case, even when there are differences in a flow velocity distribution in the X-axis direction in the discharge ports 131c, the processing fluid may flow uniformly in the X-axis direction without being affected by such a flow velocity distribution. The first holes 211h are provided side by side along an inclined surface of the first discharger 211. Each first hole 211h may be configured to discharge the processing fluid in a direction inclined with respect to a horizontal direction. For example, each first hole 211h is formed in a plate thickness direction of the first discharger 211 and configured to discharge the processing fluid obliquely upward. In this case, it is possible to reduce a flow of the processing fluid directed toward a radially outer end of the substrate W. This reduces evaporation of a liquid film formed on the radially outer end of the substrate W and reduces collapse of a pattern on the radially outer end of the substrate W. Each first hole 211h may be configured to discharge the processing fluid towards the gap G1 between the first surface 110s and the second surface 131s. In this case, retention of the processing fluid in the seal groove 161 is reduced, making it difficult for foreign substances such as IPA residue to remain in the seal groove 161.

The second discharger 212 is inclined downward from an end of the first discharger 211 on the negative side of the Y-axis toward the positive side of the Y-axis. The second discharger 212 is provided with second holes 212h through which the processing fluid is able to flow. The second holes 212h are provided side by side along the X-axis. Each second hole 212h may be arranged so as to be misaligned with each discharge port 131c in the X-axis direction. In this case, even when there are differences in a flow velocity distribution in the X-axis direction in the discharge ports 131c, the processing fluid may flow uniformly in the X-axis direction without being affected by such a flow velocity distribution. The second holes 212h are provided sided by side along an inclined surface of the second discharger 212. Each second hole 212h may be configured to discharge the processing fluid in a direction inclined with respect to a horizontal direction. For example, each second hole 212h is formed in a plate thickness direction of the second discharger 212 and configured to discharge the processing fluid obliquely downward. In this case, it is possible to reduce a flow of the processing fluid directed toward the radially outer end of the substrate W. This reduces evaporation of the liquid film formed on the radially outer end of the substrate W and reduces collapse of a pattern on the radially outer end of the substrate W. Each second hole 212h may be configured to discharge the processing fluid towards the gap G1 between the first surface 110s and the second surface 131s. In this case, retention of the processing fluid in the seal groove 161 is reduced, making it difficult for foreign substances such as IPA residue to remain in the seal groove 161.

In the vertical cross-section perpendicular to the X-axis, a position P5 of the apex of the nozzle 210 is lower than a position P6 of an end of the substrate W held at the holding position on the positive side of the Y-axis. In a state in which the substrate W is held by the holder 120, a first distance Z1 between a first virtual plane Wa, including an upper surface of the substrate W, and a ceiling surface 110a of the processing container 110 is shorter than a second distance Z2 between a second virtual plane Wb, including a lower surface of the substrate W, and a bottom surface 110b of the processing container 110. That is, the first distance Z1 and the second distance Z2 satisfy a relationship of Z1<Z2. A ratio of the first distance Z1 to the second distance Z2 is, for example, in a range of 20:80 to 40:60.

The first discharger 211 is configured to discharge a first discharge amount of the processing fluid from a position above the first virtual plane Wa. The second discharger 212 is configured to discharge a second discharge amount of the processing fluid from a position below the second virtual plane Wb. The first discharger 211 and the second discharger 212 are configured to discharge the processing fluid such that a magnitude relationship between the first discharge amount and the second discharge amount corresponds to a magnitude relationship between the first distance Z1 and the second distance Z2. In the example shown in FIG. 3, the first distance Z1 is shorter than the second distance Z2. Therefore, the first discharger 211 is configured to discharge the first discharge amount of the processing fluid that is smaller than the second discharge amount of the processing fluid, and the second discharger 212 is configured to discharge the second discharge amount of the processing fluid. In this case, an airflow inside the processing container 110 is stabilized, thus making it possible to improve uniformity of the airflow inside the processing container 110. For example, it is possible to reduce the first discharge amount relative to the second discharge amount by configuring a total area of the first holes 211h provided at the first discharger 211 to be smaller than a total area of the second holes 212h provided at the second discharger 212. For example, it is possible to reduce the first discharge amount relative to the second discharge amount by configuring the number of the first holes 211h provided at the first discharger 211 to be smaller than the number of the second holes 212h provided at the second discharger 212. For example, it is possible to reduce the first discharge amount relative to the second discharge amount by configuring a diameter of each of the first holes 211h provided at the first discharger 211 to be smaller than a diameter of each of the second holes 212h provided at the second discharger 212.

A ratio of the first discharge amount to the second discharge amount may be equal to the ratio of the first distance Z1 to the second distance Z2. In this case, the airflow inside the processing container 110 tends to be particularly stable.

A position P1 of an end of the ceiling surface 110a of the processing container 110 on the positive side of the Y-axis may be located lower than a position P2 of an end of a ceiling surface of the recess 131a of the supply body 131 on the negative side of the Y-axis. In this case, a part of the first surface 110s, which is continuous with the ceiling surface 110a of the processing container 110, faces the supply space S2 without facing the second surface 131s. Accordingly, a portion of the processing fluid discharged from each first hole 211h collides with the first surface 110s facing the supply space S2 and is guided toward the gap G1 between the first surface 110s and the second surface 131s. As a result, retention of the processing fluid in the seal groove 161 is reduced, making it difficult for foreign substances such as IPA residue to remain in the seal groove 161. The first surface 110s facing the supply space S2 is an example of a guide.

A position P3 of an end of the bottom surface 110b of the processing container 110 on the positive side of the Y-axis may be located higher than a position P4 of an end of a bottom surface of the recess 131a of the supply body 131 on the negative side of the Y-axis. In this case, a part of the first surface 110s, which is continuous with the bottom surface 110b of the processing container 110, faces the supply space S2 without facing the second surface 131s. Accordingly, a portion of the processing fluid discharged from each second hole 212h collides with the first surface 110s facing the supply space S2 and is guided toward the gap G1 between the first surface 110s and the second surface 131s. As a result, retention of the processing fluid in the seal groove 161 is reduced, making it difficult for foreign substances such as IPA residue to remain in the seal groove 161. The first surface 110s facing the supply space S2 is an example of the guide.

### Second Example

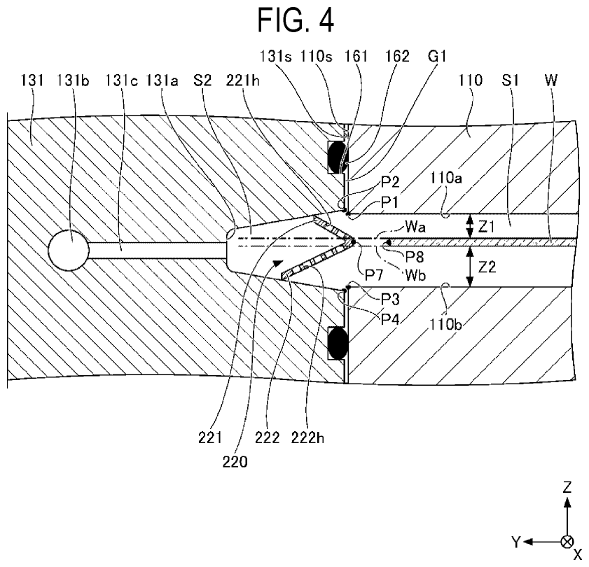

A nozzle 220 according to a second example is described with reference to FIG. 4. The nozzle 220 is applicable as the nozzle 132 described above. FIG. 4 is a diagram illustrating the nozzle 220 according to the second example. FIG. 4 is a cross-sectional view taken along line A-A in FIG. 2. In FIG. 4, illustration of the holder 120 is omitted.

The nozzle 220 of the second example differs from the nozzle 210 of the first example in that, in a vertical cross-section perpendicular to the X-axis, a position P7 of an apex of the nozzle 220 is at the same height as a position P8 of the end of the substrate W held at the holding position. Hereinafter, configurations of the nozzle 220, which are different from those of the nozzle 210 of the first example, are mainly described.

The nozzle 220 includes a first discharger 221 and a second discharger 222. The first discharger 221 is inclined upward from the negative side of the Y-axis toward the positive side of the Y-axis. The first discharger 221 is provided with first holes 221h through which the processing fluid is able to flow. The second discharger 222 is inclined downward from an end of the first discharger 221 on the negative side of the Y-axis toward the positive side of the Y-axis. A length of the second discharger 222 along the Y-axis may be longer than a length of the first discharger 221 along the Y-axis. The second discharger 222 is provided with second holes 222h through which the processing fluid is able to flow.

In the vertical cross-section perpendicular to the X-axis, the position P7 of the apex of the nozzle 220 is at the same height as the position P8 of the end of the substrate W held at the holding position.

The first discharger 221 is configured to discharge a first discharge amount of the processing fluid from a position above the first virtual plane Wa. The second discharger 222 is configured to discharge a second discharge amount of the processing fluid from a position below the second virtual plane Wb. The first discharger 221 and the second discharger 222 are configured to discharge the processing fluid such that a magnitude relationship between the first discharge amount and the second discharge amount corresponds to a magnitude relationship between the first distance Z1 and the second distance Z2. In the example shown in FIG. 4, the first distance Z1 is shorter than the second distance Z2. Therefore, the first discharger 221 is configured to discharge the first discharge amount of the processing fluid that is smaller than the second discharge amount of the processing fluid, and the second discharger 222 is configured to discharge the second discharge amount of the processing fluid. In this case, an airflow inside the processing container 110 is stabilized, thus making it possible to improve the uniformity of the airflow inside the processing container 110. For example, it is possible to reduce the first discharge amount relative to the second discharge amount by configuring a total area of the first holes 221h provided at the first discharger 221 to be smaller than a total area of the second holes 222h provided at the second discharger 222. For example, it is possible to reduce the first discharge amount relative to the second discharge amount by configuring the number of the first holes 221h provided at the first discharger 221 to be smaller than the number of the second holes 222h provided at the second discharger 222. For example, it is possible to reduce the first discharge amount relative to the second discharge amount by configuring a diameter of each of the first holes 221h provided at the first discharger 221 to be smaller than a diameter of each of the second holes 222h provided at the second discharger 222.

A ratio of the first discharge amount to the second discharge amount may be equal to a ratio of the first distance Z1 to the second distance Z2. In this case, the airflow inside the processing container 110 tends to be particularly stable.

### [Substrate Processing Method]

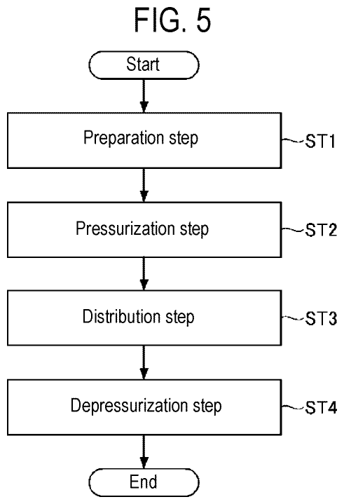

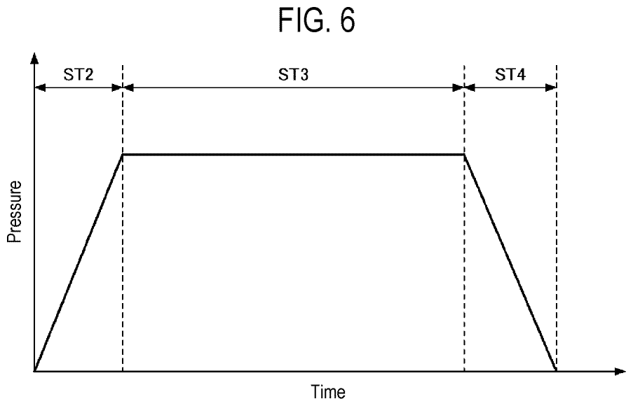

A substrate processing method executed by using the substrate processing apparatus 1 is described with reference to FIGS. 5 and 6. The substrate processing method described below is automatically executed under control of the control circuit 5 based on a process recipe and a control program stored in the storage 5b. FIG. 5 is a flowchart illustrating the substrate processing method according to an embodiment. FIG. 6 is a diagram illustrating a pressure variation in each process. In FIG. 6, a horizontal axis denotes time and a vertical axis denotes the internal pressure of the processing container 110.

As illustrated in FIG. 5, the substrate processing method according to the embodiment includes a preparation step ST1, a pressurization step ST2, a distribution step ST3, and a depressurization step ST4.

In the preparation step ST1, the substrate W is introduced into the processing container 110. The substrate W is loaded onto the holder 120 in a state where the substrate W is cleaned and filled with IPA in a recess of a pattern of the surface of the substrate W.

The pressurization step ST2 is performed after the preparation step ST1. In the pressurization step ST2, the opening/closing valves V11 and V12 become an open state and the opening/closing valve V13 becomes a closed state. As a result, the processing fluid of the fluid supply source S11 is discharged from the discharge ports 131c of the fluid supplier 130 into the processing container 110 via the supply passage L11. In the pressurization step ST2, the opening/closing valve V13 is closed, and thus the processing fluid does not flow out of the processing container 110. Therefore, as illustrated in FIG. 6, the internal pressure of the processing container 110 gradually increases. In the pressurization step ST2, a pressure of the processing fluid supplied into the processing container 110 is lower than a threshold pressure. For this reason, the processing fluid is supplied into the processing container 110 in a gaseous state. Subsequently, the internal pressure of the processing container 110 increases with the progress of the filling of the processing fluid into the processing container 110. When the internal pressure of the processing container 110 exceeds the threshold pressure, the processing fluid present in the processing container 110 becomes a supercritical state from the gaseous state. In the pressurization step ST2, when the internal pressure of the processing container 110 reaches a predetermined pressure that is higher than the threshold pressure, the pressurization step ST2 ends and the distribution step ST3 is performed.

The distribution step ST3 is performed after the pressurization step ST2. In the distribution step ST3, the opening/closing valves V11, V12, and V13 become an open state. As a result, the processing fluid of the fluid supply source S11 is discharged from the discharge ports 131c of the fluid supplier 130 into the processing container 110 via the supply passage L11. The processing fluid supplied into the processing container 110 is drained from the interior of the processing container 110 via the drain passage L12. In the distribution step ST3, the supply of the processing fluid into the processing container 110 and the drain of the processing fluid from the interior of the processing container 110 are performed simultaneously. Accordingly, as illustrated in FIG. 6, the internal pressure of the processing container 110 is maintained at a constant level or a substantially constant level. By performing the distribution step ST3, the replacement of IPA with the processing fluid in the recess of the pattern of the substrate W is facilitated. When the replacement of the IPA with the processing fluid in the recess of the pattern is completed, the distribution step ST3 ends and the depressurization step ST4 is performed.

The depressurization step ST4 is performed after the distribution step ST3. In the depressurization step ST4, the opening/closing valve V13 becomes an open state, and the opening/closing valves V11 and V12 become a closed state. As a result, the processing fluid is drained from the interior of the processing container 110 in a state in which the processing fluid is not supplied into the processing container 110. Accordingly, as illustrated in FIG. 6, the internal pressure of the processing container 110 is gradually lowered. When the internal pressure of the processing container 110 becomes lower than the threshold pressure of the processing fluid by the depressurization step ST4, the processing fluid in the supercritical state is vaporized and released from the recess of the pattern. In this way, a drying process for one substrate W is terminated.

According to an embodiment, in the pressurization step ST2 and the distribution step ST3, the nozzle 132 (the nozzle 210 and the nozzle 220) discharges the processing fluid such that the magnitude relationship between the first discharge amount and the second discharge amount corresponds to the magnitude relationship between the first distance Z1 and the second distance Z2. In this case, the airflow inside the processing container 110 is stabilized, thus making it possible to improve the uniformity of the airflow inside the processing container 110.

### [Analysis Results]

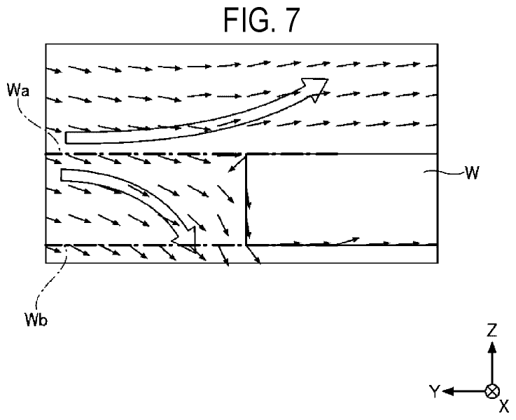

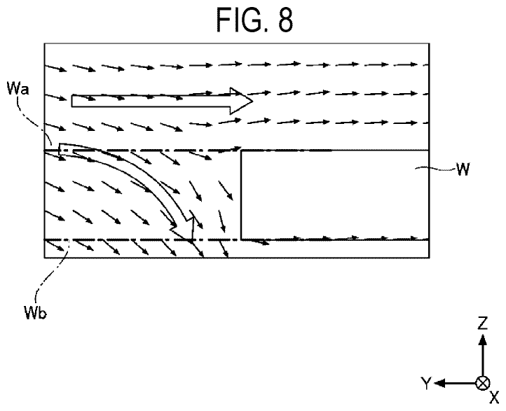

The flow of the processing fluid was analyzed with reference to FIGS. 7 and 8 based on simulations for the case in which the processing fluid is supplied into the processing container from a lateral side of the processing container by using nozzles having different ratios of the first discharge amount to the second discharge amount. In the simulations, the ratio of the first distance Z1 to the second distance Z2 was set to 1:2. FIGS. 7 and 8 are diagrams illustrating analysis results of the flow of the processing fluid. In FIGS. 7 and 8, directions of the flow of the processing fluid in the vicinity of the end of the substrate W on the positive side of the Y-axis are indicated by black arrows.

FIG. 7 illustrates the flow of the processing fluid when the ratio of the first discharge amount to the second discharge amount is 1:2, that is, when the magnitude relationship between the first discharge amount and the second discharge amount corresponds to the magnitude relationship between the first distance Z1 and the second distance Z2. As illustrated in FIG. 7, it is seen that there is almost no inflow of the processing fluid from a position above the first virtual plane Wa to a position below the second virtual plane Wb, and there is almost no inflow of the processing fluid from the position below the second virtual plane Wb to the position above the first virtual plane Wa.

FIG. 8 illustrates the flow of the processing fluid when the ratio of the first discharge amount to the second discharge amount is 1:1, that is, when the magnitude relationship between the first discharge amount and the second discharge amount does not correspond to the magnitude relationship between the first distance Z1 and the second distance Z2. As illustrated in FIG. 8, since a flow rate of the processing fluid discharged from the position above the first virtual plane Wa is large, it is seen that the processing fluid flows from the position above the first virtual plane Wa toward the position below the second virtual plane Wb.

From the above results, it is considered that, when the magnitude relationship between the first discharge amount and the second discharge amount corresponds to the magnitude relationship between the first distance Z1 and the second distance Z2, the airflow inside the processing container 110 is stabilized, thus making it possible to improve the uniformity of the airflow inside the processing container 110.

According to the present disclosure in some embodiments, it is possible to improve uniformity of an airflow inside the processing container.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a processing container;
a holder configured to hold a substrate in a horizontal orientation at a holding position inside the processing container; and
a fluid supplier configured to supply a processing fluid into the processing container from a lateral side of the processing container,
wherein, in a state in which the substrate is held by the holder, a first distance between a first virtual plane, including an upper surface of the substrate, and a ceiling surface of the processing container is different from a second distance between a second virtual plane, including a lower surface of the substrate, and a bottom surface of the processing container,
wherein the fluid supplier includes a nozzle configured to change a flow of the processing fluid,
wherein the nozzle includes:
a first discharger configured to discharge a first discharge amount of the processing fluid from a position above the first virtual plane; and
a second discharger configured to discharge a second discharge amount of the processing fluid from a position below the second virtual plane, and
wherein a magnitude relationship between the first discharge amount and the second discharge amount corresponds to a magnitude relationship between the first distance and the second distance.

2. The substrate processing apparatus of claim 1, wherein the first distance is shorter than the second distance.

3. The substrate processing apparatus of claim 2, wherein the first discharger includes first holes,
wherein the second discharger includes second holes, and
wherein a total area of the first holes is smaller than a total area of the second holes.

4. The substrate processing apparatus of claim 3, wherein the number of the first holes is smaller than the number of the second holes.

5. The substrate processing apparatus of claim 4, wherein the processing container includes an opening at an end,
wherein the fluid supplier includes a supply body configured to cover the opening, and
wherein the nozzle is installed on the supply body.

6. The substrate processing apparatus of claim 5, wherein the processing container includes a first surface configured to surround the opening and face the supply body,
wherein the supply body includes a second surface configured to face the first surface, and
wherein the substrate processing apparatus further comprises:
a sealing member provided between the first surface and the second surface and configured to seal a gap between the first surface and the second surface; and
a guide configured to guide the processing fluid discharged from the nozzle toward the gap.

7. The substrate processing apparatus of claim 1, wherein the nozzle has a V shape with an apex on a side toward the substrate in a vertical cross-section, and
wherein, in the state in which the substrate is held by the holder, a position of the apex of the nozzle is lower than a position of an end of the substrate on a side toward the nozzle.

8. The substrate processing apparatus of claim 1, wherein the nozzle has a V shape with an apex on a side toward the substrate in a vertical cross-section, and
wherein, in the state in which the substrate is held by the holder, a position of the apex of the nozzle is at a height equal to a position of an end of the substrate on a side toward the nozzle.

9. The substrate processing apparatus of claim 1, wherein the processing fluid is in a supercritical state or a gaseous state.

10. The substrate processing apparatus of claim 1, wherein the processing container includes an opening at an end,
wherein the fluid supplier includes a supply body configured to cover the opening, and
wherein the nozzle is installed on the supply body.

11. A substrate processing method using a substrate processing apparatus,
wherein the substrate processing apparatus includes:
a processing container;
a holder configured to hold a substrate in a horizontal orientation at a holding position inside the processing container; and
a fluid supplier configured to supply a processing fluid into the processing container from a lateral side of the processing container,
wherein, in a state in which the substrate is held by the holder, a first distance between a first virtual plane, including an upper surface of the substrate, and a ceiling surface of the processing container is different from a second distance between a second virtual plane, including a lower surface of the substrate, and a bottom surface of the processing container,
wherein the fluid supplier includes a nozzle configured to change a flow of the processing fluid,
wherein the nozzle includes:
a first discharger configured to discharge a first discharge amount of the processing fluid from a position above the first virtual plane; and
a second discharger configured to discharge a second discharge amount of the processing fluid from a position below the second virtual plane, and
wherein the fluid supplier supplies the processing fluid into the processing container by changing the flow of the processing fluid using the nozzle so that a magnitude relationship between the first discharge amount and the second discharge amount corresponds to a magnitude relationship between the first distance and the second distance.
